(19) United States
(12) Patent Application Publication
(10) Pub. No.: US 2011/0248954 A1
(43) Pub. Date: Oct. 13, 2011

(54) TOUCH PANEL DEVICE AND METHOD FOR MANUFACTURING THE SAME, AND DISPLAY DEVICE

(76) Inventors: Hiroshi Hamada, Osaka (JP); Minoru Mayumi, Osaka (JP); Seiji Satoh, Osaka (JP)

(21) Appl. No.: 12/998,912

(22) PCT Filed: Dec. 9, 2009
(86) PCT No.: PCT/JP2009/006730

§ 371 Date: Jun. 15, 2011

(30) Foreign Application Priority Data
Jan. 7, 2009 (JP) 2009-001868

(51) Int. Cl. G09G 3/36; H05K 13/00; G06F 3/045

(52) U.S. Cl. 345/174; 29/592.1; 345/104

(57) ABSTRACT

A touch panel device includes a plurality of touch position detection electrodes provided in a touch area, and a detection circuit configured to detect a touch position or positions based on a capacitance or capacitances formed between the touch position detection electrodes and a touching object. The touch position detection electrodes include a first electrode and second electrodes formed along a curved substrate surface. The first electrode has a center portion provided at a center of the touch area, and a plurality of tip portions radially extending from the center portion to reach a periphery of the touch area. The second electrodes are located in a region including the periphery of the touch area, and one of the second electrodes is located between each adjacent pair of the tip portions.

### TECHNICAL FIELD

The present invention relates to curved touch panel devices and methods for manufacturing the same, and display devices.

### BACKGROUND ART

In recent years, touch panel (touch screen) devices for detecting a touch position have been widely used (see, for example, Patent Document 1 etc.). Most touch panel devices are attached to display devices, such as liquid crystal display panels etc.

There are different types of touch panel devices based on different operating principles: resistive; capacitive; infrared; ultrasonic; electromagnetic inductive; etc. Of them, capacitive touch panel devices are known to be suitable for display devices because they are not likely to impair the optical characteristics of the display device.

There are two types of capacitive touch panel devices: surface capacitive; and projected capacitive. A typical surface capacitive touch panel device includes a transparent electrode which is provided on an entire touch area in order to detect a position, a plurality of segment electrodes which are provided along the perimeter of the transparent electrode in order to obtain a uniform distribution of electric field in the touch area, and a current detection circuit which detects a current flowing via the segment electrodes. The transparent electrode is covered with an insulating film for protection. When the insulating film of the touch area is touched, the transparent electrode is grounded via a capacitance formed between the transparent electrode and the human body at a touch position. A change occurs in the impedance between each segment electrode and the ground, depending on the touch position, and the change is detected by the current detection circuit. Thus, the touch position is detected based on the change in the impedance.

Patent Document 1 also describes that the segment electrodes are concentrically located and equally spaced along the perimeter of the rectangular touch area, and in addition, the segment electrodes located at concentric positions are equal in length, whereby the linearity of the electric field is enhanced.

A typical projected capacitive touch panel device includes X electrodes and Y electrodes arranged in a matrix. A change in the capacitance to ground of each electrode or a change in a mutual capacitance at an intersection between the X and Y electrodes, which are caused by touching the panel, is detected by a capacitance detection circuit to detect a touch position.

Patent Document 2 describes a touch sensor having a ring-shaped touch area in which a plurality of electrodes are arranged in a closed loop. The touch sensor is configured so that when a touch position is moved along the closed loop in the touch area, a signal corresponding to the movement operation is generated.

### CITATION LIST

### Patent Documents

PATENT DOCUMENT 1: Japanese Translation of PCT International Application No. 2005-530274

PATENT DOCUMENT 2: Japanese Translation of PCT International Application No. 2005-522797

Patent Document 3: WO2007/099733

### SUMMARY OF THE INVENTION

### Technical Problem

In the conventional art, because display devices are flat, only flat touch panels have been put into practice. The touch panel described in Patent Document 1 is assumed to have a flat shape, a rectangular touch area, and an output specified by the Cartesian coordinate system. The touch sensor of Patent Document 2 is also assumed to generate a signal based on touch input operation in a circular direction along the closed loop in a plane, however, it is not assumed that a center portion surrounded by the closed loop does not serve as a touch detection area, and neither the function of detecting a touch position in a radial direction nor the function of detecting scroll operation across the center portion is suggested. Note that Patent Document 2 does not describe or suggest that the touch sensor is transparent or that the touch sensor is provided on a display device so that the display screen of the display device can be seen.

On the other hand, there may be a potential demand for a curved (non-flat) touch panel as a user interface appealing to the sensibilities of the user. However, in the case of the resistive, infrared, ultrasonic, and electromagnetic inductive technologies, it is impossible to produce a non-flat touch panel, or it is considerably difficult to produce one which can be put into practice. In contrast to this, in the case of the capacitance technology, it is possible to produce a non-flat panel which can be put into practice, and such a non-flat panel has been proposed by the present inventors in Patent Document 3.

However, Patent Document 3 only describes a single transparent electrode which is formed in a touch area, and does not mention so-called multi-touch.

The present invention has been made in view of the above problems. It is a major object of the present invention to provide a curved touch panel which supports multi-touch and provides an increased number of types of touch input operation, thereby improving the convenience of the user.

### Solution to the Problem

In order to achieve the object, a touch panel device according to the present invention includes a touch area configured to detect a position or positions of a touch or touches made by a touching object, a plurality of touch position detection electrodes provided in the touch area, and a detection circuit configured to detect the touch position or positions based on a capacitance or capacitances formed between the touch position detection electrodes and the touching object. The plurality of touch position detection electrodes include a first electrode and second electrodes formed along a curved substrate surface. The first electrode has a center portion provided at a center of the touch area, and a plurality of tip portions radially extending from the center portion to reach a periphery of the touch area. The second electrodes are located in a region including the periphery of the touch area, and one of the second electrodes is located between each adjacent pair of the tip portions.

The curved substrate surface may be a non-developable surface.

The curved substrate surface may be a rotationally symmetric (e.g., convex or concave) surface.

The detection circuit may be configured to detect whether or not the center portion of the first electrode is touched, and detect at least one of a distance and an azimuth of the touch position from a center of the rotational symmetry.

The detection circuit may be configured to detect the touch position which is moved from the tip portion on one side through the center portion to the tip portion on the opposite side, and detect the touch position which is moved along the periphery of the touch area.

The first electrode may be coupled to the detection circuit in the plurality of tip portions as viewed from above. The detection circuit may be configured to, when the touch position is moved between tips of the first electrode along the plurality of tip portions and the center portion, detect vertical or horizontal scroll operation based on changes in capacitance values detected from the plurality of tip portions.

The second electrodes may be formed in the shape of a wedge.

The detection circuit may include a capacitance detection circuit configured to detect a capacitance occurring in each of the first and second electrodes, or an impedance detection circuit configured to detect an impedance occurring in each of the first and second electrodes.

The second electrodes may be coupled, separately or in groups, to the capacitance detection circuit or the impedance detection circuit.

The tip portions of the first electrode may be coupled to the capacitance detection circuit or the impedance detection circuit. The detection circuit may be configured to compare signals from the tip portions detected by the capacitance detection circuit or the impedance detection circuit, to detect the touch position or positions in the center portion, or scroll operation in a direction along a perimeter of the touch area.

The detection circuit may be configured to compare signals from the second electrodes detected by the capacitance detection circuit or the impedance detection circuit, to detect the touch position or positions in a perimeter portion of the touch area, or scroll operation in a direction along a perimeter of the touch area.

The detection circuit may be configured to compare signals from the tip portions detected by the capacitance detection circuit or the impedance detection circuit with signals from the second electrodes detected by the capacitance detection circuit or the impedance detection circuit, to detect the touch position or positions in a radial direction from the center of the touch area, or scroll operation in a direction along a perimeter of the touch area.

Also, a touch panel device according to the present invention includes a touch area configured to detect a position or positions of a touch or touches made by a touching object, a plurality of touch position detection electrodes provided in the touch area, and a detection circuit configured to detect the touch position or positions based on a capacitance or capacitances formed between the touch position detection electrodes and the touching object. The plurality of touch position detection electrodes include a plurality of first electrodes and a plurality of second electrodes formed along a curved substrate surface. The plurality of first electrodes are provided at a center of the substrate surface, and the set of the plurality of first electrodes as a whole is formed in the shape of a circle. The plurality of second electrodes are provided outside the first electrodes, and the set of the plurality of second electrodes as a whole is formed in the shape of a ring. The detection circuit is configured to detect at least one of a distance and an azimuth of the touch position from a center of the rotational symmetry, and the touch position which is moved on the first and second electrodes in a diameter direction of the touch area as viewed from above.

The curved substrate surface may be a non-developable surface.

The curved substrate surface may be a rotationally symmetric (e.g., convex or concave) surface.

The plurality of touch position detection electrodes may include a plurality of third electrodes provided outside the second electrodes, and the set of the plurality of third electrodes as a whole is formed in the shape of a ring. The detection circuit may be configured to detect the touch position which is moved on the first, second, and third electrodes in the diameter direction of the touch area as viewed from above, or the touch position which is moved in a circular direction in each of the circular region of the set of the plurality of first electrodes and the ring-shaped region of the set of the plurality of second and third electrodes.

Also, a display device according to the present invention includes the touch panel device, and a display panel facing the touch panel device.

The display panel may be a liquid crystal display panel.

Also, a touch panel device manufacturing method according to the present invention is a method for manufacturing a touch panel device including a touch area configured to detect a position or positions of a touch or touches made by a touching object, a plurality of touch position detection electrodes provided in the touch area, and a detection circuit configured to detect the touch position or positions based on a capacitance or capacitances formed between the touch position detection electrodes and the touching object. The method includes the steps of forming a substrate having a curved surface, and forming a transparent conductive film having a predetermined shape along the curved surface of the substrate to form a first electrode and second electrodes. In the step of forming the first and second electrodes, the first electrode is formed to have a center portion provided at a center of the touch area, and a plurality of tip portions radially extending from the center portion to reach a periphery of the touch area, and the second electrodes are located in a region including the periphery of the touch area, and one of the second electrodes is located between each adjacent pair of the tip portions.

—Actions—

Next, actions of the present invention will be described.

In the touch panel device, when a touching object touches the touch area, a capacitance or capacitances are formed between the touching object and the touch position detection electrodes, and the detection circuit detects a position or positions of a touch or touches based on a change or changes in the capacitance or capacitances.

The touch position detection electrodes include the first electrode and the second electrodes formed along the curved substrate surface. The first electrode has the center portion, and the tip portions radially extending from the center portion. One of the second electrodes is located between each adjacent pair of the tip portions. Therefore, for example, it is possible to detect whether or not the center portion of the first electrode is touched, and detect a touch position which is moved along the periphery of the touch area.

The curved substrate surface may be a non-developable surface, or a rotationally symmetric (e.g., convex or concave) surface. Here, a “developable surface” refers to a surface which can be flattened into a plane without stretching, compressing, or wrinkling. In other words, the “non-developable surface” refers to a surface which cannot be flattened into a plane without stretching, compressing, or wrinkling.

A touch position which is moved from a tip portion on one side through the center portion to another tip portion on the opposite side can be detected. In addition, a touch position which is moved along the periphery of the touch area can be detected.

Impedances detected in the tip portions depend on the distances between the tip portions and a touch position. Therefore, when a touch position is moved upward, downward, leftward, or rightward along the tip portions and the center portion as viewed from above, vertical or horizontal scroll operation can be detected based on changes in the impedances.

The detection circuit can detect a touch position in the center portion, or scroll operation in a perimeter direction of the touch area, by comparing signals from the tip portions detected by the capacitance detection circuit or the impedance detection circuit included in the detection circuit.

The detection circuit can also detect a touch position in a perimeter portion of the touch area, or scroll operation in the perimeter direction, by comparing signals from the second electrodes detected by the capacitance detection circuit or the impedance detection circuit.

The detection circuit can also detect a touch position in a radial direction from the center of the touch area, or scroll operation in a perimeter direction of the touch area, by comparing signals from the tip portions and the second electrodes detected by the capacitance detection circuit or the impedance detection circuit.

The detection circuit may be configured to, when changes occur in signals from the second electrodes or the tip portions of the first electrode, detect multi-touch operation which is performed by gripping the touch area with a plurality of fingers and rotating the fingers, by appropriate signal processing.

The touch panel device may be provided to face a display panel, such as a liquid crystal display panel etc., thereby providing a display device which can detect a touch position.

The touch panel device may be manufactured as follows. Initially, a substrate having a curved surface is formed. Thereafter, on the curved substrate surface, a transparent conductive film is formed in a predetermined shape along the surface. As a result, the first electrode and the second electrodes can be formed.

### Advantages of the Invention

According to the present invention, the touch position detection electrodes include the first and second electrodes formed along a rotationally symmetric (e.g., convex or concave) substrate surface. The first electrode has the center portion, and the tip portions radially extending from the center portion, and one of the second electrodes is located between each adjacent pair of the tip portions. As a result, not only touch input can be performed on the curved touch panel with high operability, but also multi-touch can be supported and the number of types of touch input operation can be increased, whereby the convenience of the user can be significantly improved. In addition, the distance and azimuth of a touch position from the center of the rotational symmetry of the substrate can be detected, so that a predetermined signal can be directly generated by a large number of types of touch input. As a result, the load of calculation required for signal generation can be reduced.

### BRIEF DESCRIPTION OF THE DRAWINGS

FIG. 1 is a plan view schematically showing a configuration of a touch panel device according to a first embodiment.

FIG. 2 is a perspective view schematically showing a configuration of a liquid crystal display device of the first embodiment.

FIG. 3 is a plan view schematically showing a configuration of a liquid crystal display device according to a second embodiment.

FIG. 4 is a plan view schematically showing a configuration of a liquid crystal display device according to a third embodiment.

FIG. 5 is a plan view schematically showing a configuration of a liquid crystal display device according to a fourth embodiment.

FIG. 6 is a plan view schematically showing a configuration of a liquid crystal display device according to a fifth embodiment.

FIG. 7 is a perspective view schematically showing a configuration of a liquid crystal display device according to a sixth embodiment.

### DESCRIPTION OF EMBODIMENTS

Embodiments of the present invention will be described in detail hereinafter with reference to the accompanying drawings. Note that the present invention is not limited to the embodiments described below.

### First Embodiment of the Invention

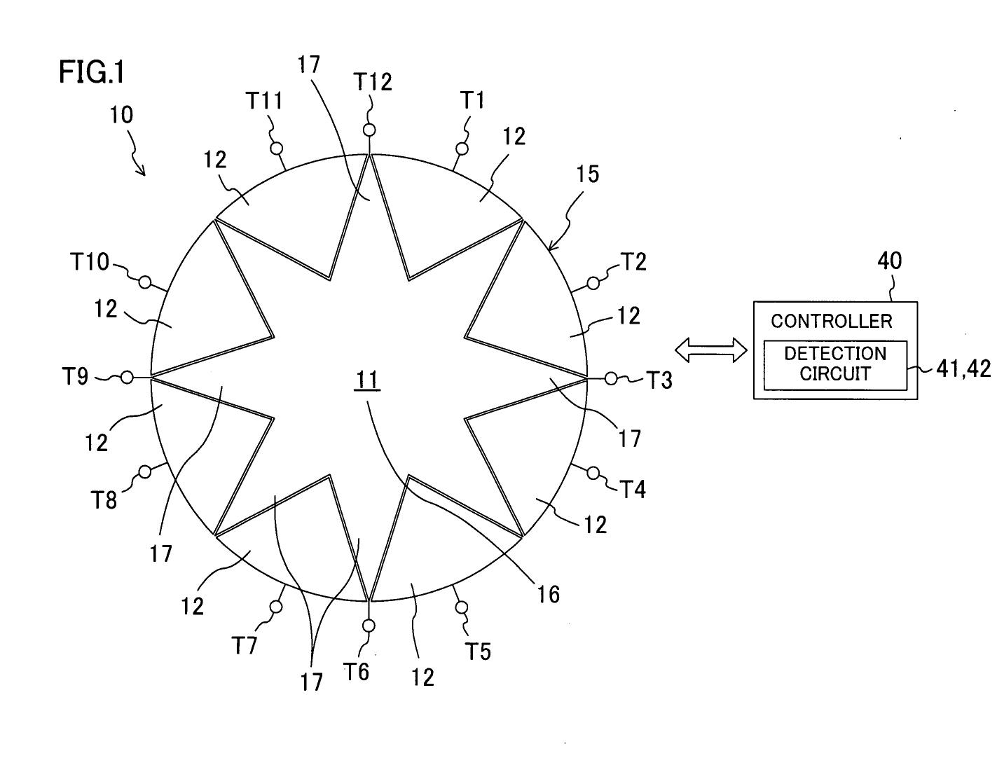

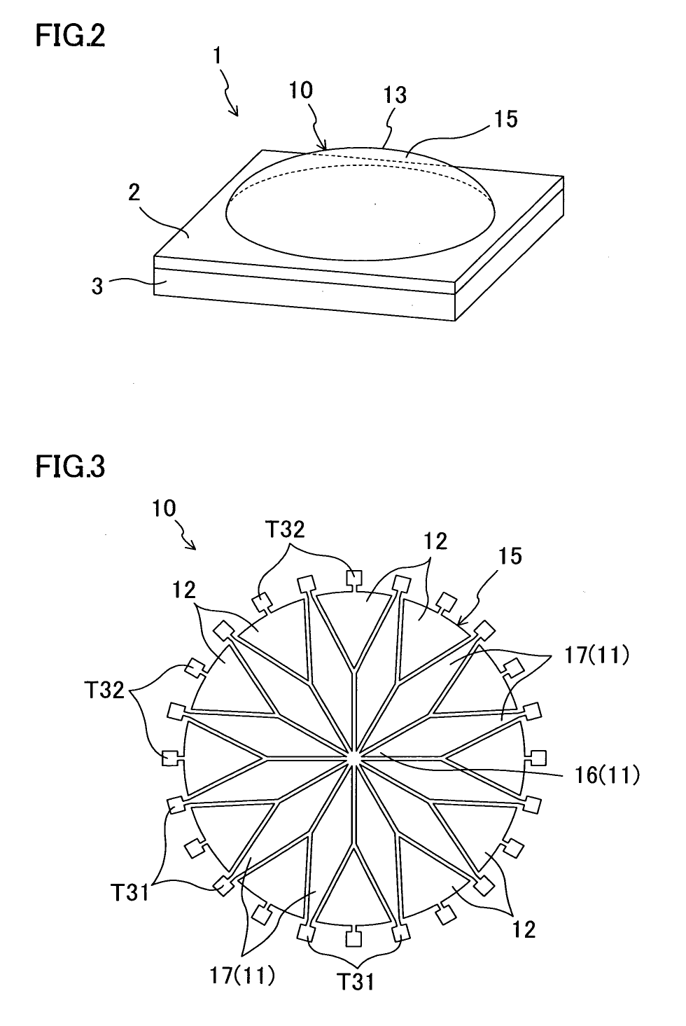

FIGS. 1 and 2 show a first embodiment of the present invention.

FIG. 1 is a plan view schematically showing a configuration of a touch panel device of this embodiment. FIG. 2 is a perspective view schematically showing a configuration of a liquid crystal display device of this embodiment. Note that, in FIG. 2, a touch position detection electrode is not shown.

In this embodiment, as an example display device, a liquid crystal display device 1 including a liquid crystal display panel 2 as the display panel will be described.

As shown in FIG. 2, the liquid crystal display device 1 includes the liquid crystal display panel 2, a backlight unit 3 which is a light source device provided on the back side of the display panel 2, and a touch panel device 10 which is provided on the opposite side of the liquid crystal display panel 2 from the backlight unit 3. In other words, the liquid crystal display panel 2 faces the touch panel device 10.

Although not shown, the liquid crystal display panel 2 includes a TFT substrate on which a plurality of pixel electrodes and a plurality of thin film transistors (TFT) serving as switching elements are provided and arranged in a matrix, a counter substrate which faces the TFT substrate and on which a color filter, a common electrode, etc. are formed, and a liquid crystal layer which is provided between the counter substrate and the TFT substrate.

The touch panel device 10 of this embodiment is used to perform various operations, such as scrolling a page displayed on the liquid crystal display panel 2, moving a pointer, selecting a menu or an icon, moving or rotating a selected image, etc.

As shown in FIG. 1, the touch panel device 10 includes a touch area 15 which is an area in which the position of a touch made by a touching object (a finger of the user, etc.) is detected, a plurality of touch position detection electrodes 11 and 12 provided in the touch area 15, and a controller 40 which is a detection circuit which detects a touch position or positions based on a change or changes in a capacitance or capacitances formed between the touch position detection electrodes 11 and 12 and the touching object.

As shown in FIG. 2, the touch panel device 10 includes a substrate 13 which is formed in the shape of a dome. The touch position detection electrodes 11 and 12 are formed along a convex surface (an outer or inner surface) of the substrate 13.

The substrate 13 is a transparent substrate which is made of, for example, a transparent resin etc., and has a major portion which is a molded object formed in the shape of a hemisphere (or a bowl-like shape forming a part of a sphere). The substrate 13 also has a flat region in a peripheral portion thereof. The substrate 13 has a thickness of, for example, about 0.2 mm to about 2 mm, more preferably about 0.5 mm to about 1 mm. Substantially the entire hemispherical substrate 13 serves as the touch area 15.

The touch position detection electrodes 11 and 12 have a first electrode 11 and second electrodes 12. The first electrode 11 and the second electrodes 12 are each a transparent electrode. The transparent electrode is made of an inorganic transparent conductive film made of ITO, IZO, ZnO₂, etc., or an organic transparent conductive film made of polythiophene, polyaniline, PEPOT/PSS, etc., or nanofibers (e.g., carbon nanotube etc.).

Specifically, when the touch panel device 10 is manufactured, the substrate 13 having a curved surface is initially formed. A planar substrate made of a transparent resin is plastically deformed into the shape of a dome while heating, so that the substrate has a curved surface.

Thereafter, the transparent conductive film made of ITO etc. is formed in a predetermined shape along the curved surface of the substrate 13, thereby forming the first electrode 11 and the second electrodes 12.

The first electrode 11 and the second electrodes 12 can be directly patterned on the substrate 13 by curved surface printing, ink jet printing, etc., or alternatively, can be patterned by forming a film on an entire surface of the substrate 13 by vacuum coating (sputtering, ion plating, CVD, vacuum deposition), spraying, dipping, or spin coating, and then performing etching or laser ablation on the film.

The temperature at which the first electrode 11 and the second electrodes 12 are formed is lower than the limit of the temperature at which the substrate 13 is resistant to heat. For example, the heat resistant temperature limit of the substrate 13 is higher than 120° C., while the formation temperature of the first electrode 11 and the second electrodes 12 is lower than 120° C. As a result, the transparent conductive film can be stably formed on the substrate 13.

As shown in FIG. 1, the first electrode 11 has a center portion 16 which is provided at a center of the touch area 15, and a plurality of tip portions 17 which radially extend from the center portion 16 to reach a periphery of the touch area 15. The center portion 16 and the tip portions 17 are integrally formed, and the first electrode 11 as a whole is formed in the shape of a star. In this embodiment, for example, there are eight tip portions 17. In order to enhance the accuracy of detection of a touch position, a larger number of tip portions 17 are preferably provided.

On the other hand, as shown in FIG. 1, the second electrodes 12 are provided in a region including the periphery of the touch area 15 (i.e., a periphery of the hemispherical substrate 13), and one of the second electrodes 12 is located between each adjacent pair of the tip portions 17. The second electrodes 12 are formed in the shape of a wedge and have substantially a constant space from the tip portions 17. The space between each second electrode 12 and the corresponding tip portion 17 is, for example, 0.1 mm or less, more preferably 0.05 mm or less.

Terminals T3, T6, T9, and T12 are provided at the tips of the tip portions 17. In FIG. 1, the terminal T12 is provided for the upper tip portion 17, the terminal T6 is provided for the lower tip portion 17, the terminal T3 is provided for the right-hand tip portion 17, and the terminal T9 is provided for the left-hand tip portion 17.

As shown in FIG. 1, terminals T1, T2, T4, T5, T7, T8, T10, and T11 are provided for the second electrodes 12 in clockwise order with the terminal T1 corresponding to one of the second electrodes 12 that is right adjacent to the tip portion 17 having the terminal T12.

The first electrode 11 is coupled to the controller 40 at the terminals T3, T6, T9, and T12 of the four tip portions 17 provided on the upper, lower, left-hand, and right-hand sides of FIG. 1 as viewed from above. The second electrodes 12 are coupled to the controller 40 at the terminals T1, T2, T4, T5, T7, T8, T10, and T11.

In one embodiment, the curved portion of the touch panel device 10 may be transparent, and the flat portion attached to a perimeter of the curved portion may not be transparent. In this case, the terminals of the transparent first electrode 11 and second electrodes 12 may be coupled to a capacitance detection circuit 41 or an impedance detection circuit 42 described below, via a non-transparent conductive material, such as silver paste etc., which is provided on the flat portion.

The controller 40 includes a capacitance detection circuit 41 which detects a change (increase) in capacitance occurring in the first electrode 11 and the second electrodes 12 due to touching, or an impedance detection circuit 42 which detects a change in impedance occurring in each of the first electrode 11 and the second electrodes 12 due to touching. The second electrodes 12 are coupled, separately or in groups, to the capacitance detection circuit 41 or the impedance detection circuit 42. Each tip portion of the first electrode 11 is coupled to the capacitance detection circuit 41 or the impedance detection circuit 42.

The controller 40 is configured to compare signals from the terminals T3, T6, T9, and T12 of the tip portions 17 detected by the capacitance detection circuit 41 or the impedance detection circuit 42, thereby detecting a touch position in the center portion 16 of the touch area 15 or scroll operation in a direction along the perimeter of the touch area 15.

The controller 40 is also configured to compare signals from the terminals T1, T2, T4, T5, T7, T8, T10, and T11 of the second electrodes 12 detected by the capacitance detection circuit 41 or the impedance detection circuit 42, thereby detecting a touch position in a perimeter portion of the touch area 15 or scroll operation in a direction along the perimeter of the touch area 15.

The controller 40 is also configured to compare signals from the tip portions 17 detected by the capacitance detection circuit 41 or the impedance detection circuit 42 with signals from the second electrodes 12 detected by the capacitance detection circuit 41 or the impedance detection circuit 42, thereby detecting a touch position in a radial direction from the center of the touch area 15 or scroll operation in a direction along the perimeter of the touch area 15.

Next, how the controller 40 detects a touch position will be described.

Firstly, the controller 40 is configured to detect whether or not the center portion 16 of the first electrode 11 is touched, and at least one of a distance and an azimuth of the touch position from the center of rotational symmetry of the touch area 15.

Specifically, when the user touches the center portion 16 with a finger, the controller 40 senses the presence or absence of a capacitance at the center portion 16 via the terminals T3, T6, T9, and T12 to detect the touch. In this case, capacitances detected at the terminals T3, T6, T9, and T12 have equal values. A predetermined region displayed on the liquid crystal display panel 2 can be selected by the touch operation.

On the other hand, by gripping and rotating the hemispherical touch area 15 with five fingers, the user can, for example, scroll a page, move a pointer, select a menu or an icon, etc., depending on the movement of a touch position along the periphery of the touch area 15.

Here, in FIG. 1, for example, when the user's fingers touch the second electrodes 12, capacitance values corresponding to the areas of regions touched by the fingers are output to the controller 40. Next, as the user's fingers are moved in a clockwise direction in FIG. 1, the areas of the touched regions of the second electrodes 12 decrease, and the areas of the touched regions of the tip portions 17 of the first electrode 11 increase. Based on the increase or decrease in the area of the touched region in each electrode, the controller 40 detects movements of the touch positions, and generates a signal of image operation corresponding to the touch position movements. This series of detection controls is similarly performed when the touch positions are continuously moved from the tip portions 17 to the next second electrodes 12 in a clockwise direction.

When the tip portions 17 for which the terminals T3 and T9 are provided are simultaneously gripped and touched at two points, capacitance values which are detected via the terminals T3 and T9 are greater than capacitance values which are detected via the terminals T6 and T12, and as a result, the controller 40 detects the two-point touch. Also, when the tip portions 17 for which the terminals T6 and T12 are simultaneously gripped and touched at two points, the two-point touch is similarly detected.

The controller 40 is also configured to detect a touch position which is moved from a tip portion 17 on one side (e.g., the tip portion 17 for which the terminal T12 is provided) through the center portion 16 to a tip portion 17 on the opposite side (e.g., the tip portion 17 for which the terminal T6 is provided).

Specifically, when the user's finger is moved on the first electrode 11 from a portion near the terminal T12 through the center portion 16 toward the terminal T6, a capacitance value detected via the terminal T12 gradually decreases while a capacitance value detected via the terminal T6 gradually increases. As a result, the controller 40 detects the movement of the touch position, and generates an operation signal corresponding to the touch position movement (pointer movement, scrolling, etc. from top to bottom). A movement of a touch position from a portion near the terminal T3 through the center portion 16 toward the terminal T9 is similarly detected.

Specifically, the controller 40 is configured to, when a touch position is moved upward, downward, leftward, or rightward, as viewed from above, along the four tip portions 17 for which the terminals T3, T6, T9, and T12 are provided and the center portion 16, detect, for example, vertical or horizontal scroll operation etc. based on changes in capacitance values detected by the four tip portions 17.

Moreover, when a touch position is moved in a diagonal direction, e.g., from center to top right, a capacitance value detected by the first electrode 11 decreases while capacitance values detected by the terminals T1 and T2 increase. Therefore, by comparing these values, the movement of the touch position in a radial direction from the center can be detected.

### Advantages of First Embodiment

Therefore, according to the first embodiment, the first electrode 11 and the second electrodes 12 (touch position detection electrodes) are formed along the surface of the rotationally symmetric curved substrate 13. The first electrode 11 has the center portion 16, and the tip portions 17 extending radially from the center portion 16. One of the second electrodes 12 is located between each adjacent pair of the tip portions 17. Therefore, not only touch input can be performed on the curved touch panel device 10 with high operability, but also the number of types of touch input operation can be increased, whereby the convenience of the user can be significantly increased. In addition, the distance and azimuth of a touch position from the center of rotational symmetry of the substrate 13 can be detected, and therefore, a predetermined signal can be generated directly from a large number of types of touch input, resulting in a decrease in the load of calculation required for signal generation.

### Second Embodiment of the Invention

FIG. 3 shows a second embodiment of the present invention.

FIG. 3 is a plan view schematically showing a configuration of a liquid crystal display device 1 according to the second embodiment. Note that, in the following embodiments, the same parts as those of FIGS. 1 and 2 are indicated by the same reference characters, and a detailed description thereof will be omitted.

While, in the first embodiment, the first electrode 11 includes a single transparent conductive film, a plurality of first electrodes 11 are provided in the second embodiment.

Specifically, as shown in FIG. 3, each first electrode 11 is formed in the shape of a rhombus. Each first electrode 11 includes a center portion 16 provided at a center of a touch area 15, and a tip portion 17 provided at a periphery of the touch area. A terminal T31 is provided for each tip portion 17.

On the other hand, a second electrode 12, which is formed in the shape of a wedge, is provided between each adjacent pair of the tip portions 17 as in the first embodiment. A terminal T32 is provided for each second electrode 12.

The first electrodes 11 and the second electrodes 12 (touch position detection electrodes 11 and 12) thus formed can provide advantages similar to those of the first embodiment.

### Third Embodiment of the Invention

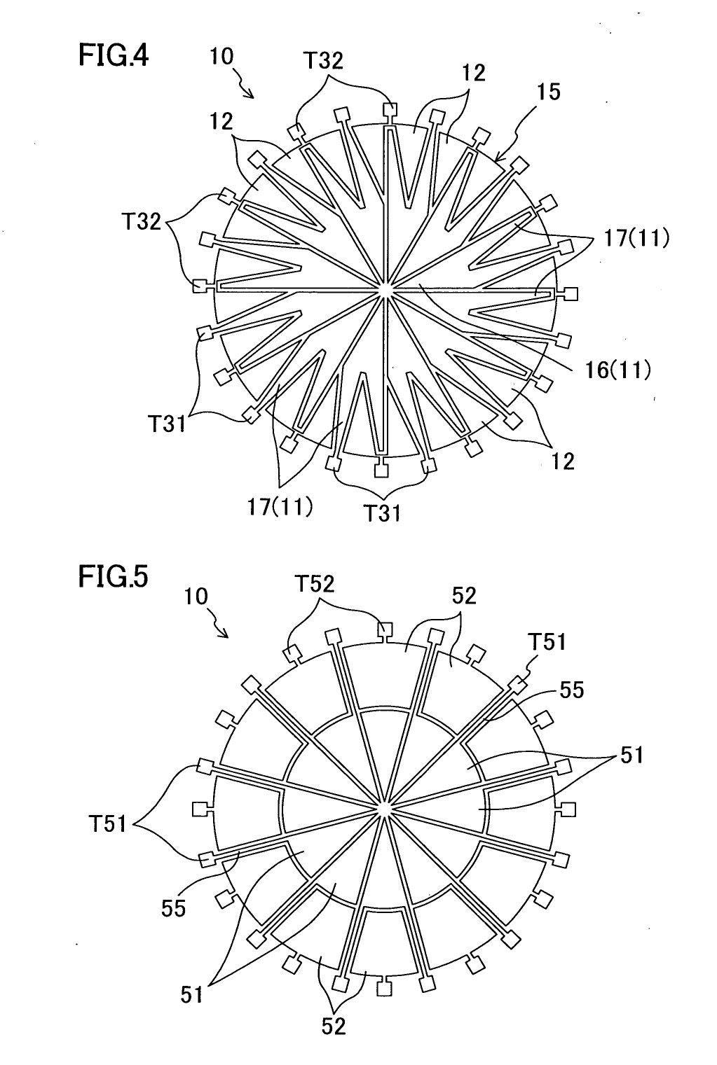

FIG. 4 shows a third embodiment of the present invention.

FIG. 4 is a plan view schematically showing a configuration of a liquid crystal display device 1 according to the third embodiment.

As shown in FIG. 4, a plurality of first electrodes 11 are provided in the third embodiment, each of which has the tip portion 17 of the second embodiment which is divided into two. In other words, the first electrodes 11 each have two tip portions 17. The tip portions 17 are radially provided and equally spaced. On the other hand, each second electrode 12 as a whole is formed in the shape of a wedge while sandwiching a single corresponding tip portion 17. A terminal T32 is provided for each second electrode 12 while a terminal T31 is provided for every other first electrode 11.

The first electrodes 11 and the second electrodes 12 thus formed can provide advantages similar to those of the first embodiment. In addition, a large number of the tip portions 17 and the second electrodes 12 provided therebetween allow detection of a movement of a touch position along a periphery of the touch area 15 with high accuracy.

### Fourth Embodiment of the Invention

FIG. 5 shows a fourth embodiment of the present invention.

FIG. 5 is a plan view schematically showing a configuration of a liquid crystal display device 1 according to the fourth embodiment.

A touch panel device 10 of the fourth embodiment includes a plurality of first electrodes 51 provided at a center of a touch area 15 (a center of a surface of a rotationally symmetric curved substrate 13), and a plurality of second electrodes 52 provided outside the first electrodes 51. As shown in FIG. 5, the first electrodes 51 are each formed in the shape of a wedge, and the set of the first electrodes 51 as a whole is formed in the shape of a circle. Each second electrode 52 is located outside the corresponding first electrode 51, whereby the set of the second electrodes 52 as a whole is formed in the shape of a ring.

A predetermined gap is provided between each adjacent pair of the second electrodes 52, and an interconnect 55 extending from each first electrode 51 is provided in the corresponding gap. A terminal T51 is provided at a tip of each interconnect 55. On the other hand, a terminal T52 is provided for each second electrode 52. The terminals T51 and T52 are coupled to a controller (not shown).

The controller, when the hemispherical touch area 15 is gripped and rotated with five fingers, generates a signal which causes, for example, page scroll operation etc., depending on a movement of a touch position along a periphery of the touch area 15 where the second electrodes 52 are provided. Also, the controller, when the user's finger is moved upward, downward, leftward, rightward etc. on the first electrodes 51 and the second electrodes 52 in a diameter direction of the touch area 15 as viewed from above, detects a movement of a touch position to generate a signal which causes, for example, pointer move operation etc.

The controller also detects a touch position which is moved in a circular direction in the circular region of the set of the first electrodes 51 and the ring-shaped region of the set of the second electrodes 52, to generate a signal which causes, for example, pointer move operation etc.

A guide groove corresponding to the ring-shaped pattern of the second electrodes in the perimeter portion may be optionally provided in order to guide rotation operation in the perimeter portion. Alternatively, a ring-shaped rib (convex portion) may be provided between the second electrodes provided in the perimeter portion and the first electrodes provided in the center portion. As a result, the operability of the touch panel device 10 can be improved.

Therefore, according to this embodiment, the number of types of touch input operation can be increased, thereby significantly improving the convenience of the user, and reducing the load of calculation required for signal generation.

### Fifth Embodiment of the Invention

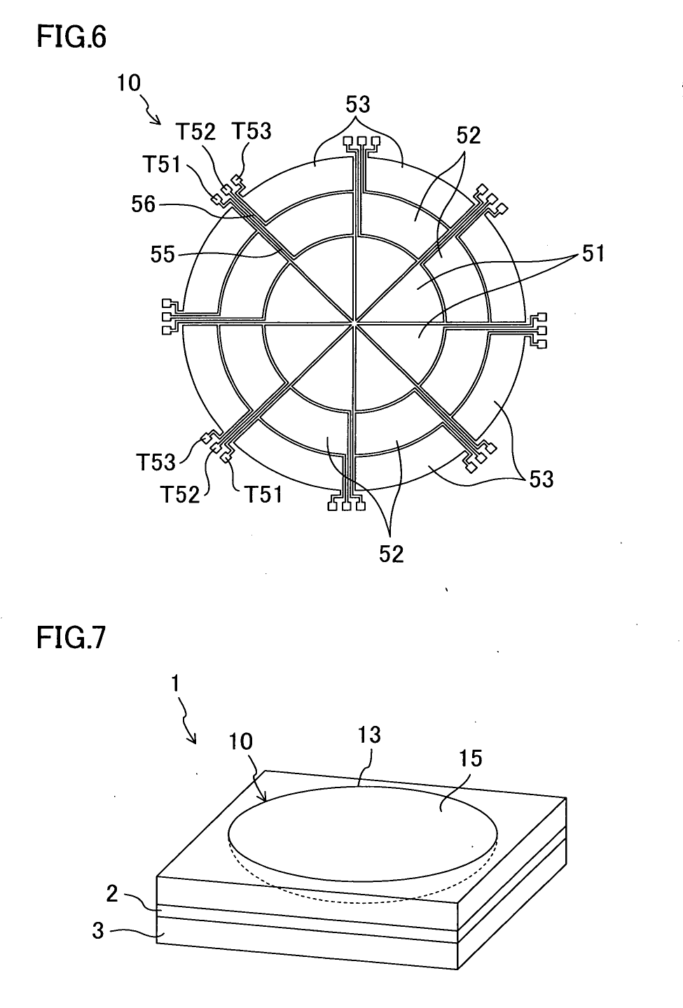

FIG. 6 shows a fifth embodiment of the present invention.

FIG. 6 is a plan view schematically showing a configuration of a liquid crystal display device 1 according to the fifth embodiment.

A touch panel device 10 of the fifth embodiment is similar to that of the fourth embodiment, except that a third electrode 53 is provided outside each second electrode 52. Specifically, in this embodiment, one first electrode 51, and one second electrode 52 and one third electrode 53 provided outside the first electrode 51, form a wedge-shaped electrode.

A predetermined gap is provided between each adjacent pair of the third electrodes 53, and an interconnect 55 extending from each first electrode 51 and an interconnect 56 extending from each second electrode 52 are provided in the corresponding gap. A terminal T51 for each first electrode 51 is provided at a tip of the corresponding interconnect 55, and a terminal T52 for each second electrode 52 is provided at a tip of the corresponding interconnect 56 and in the vicinity of the corresponding terminal 51. A terminal T53 for each third electrode 53 is provided in the vicinity of the corresponding terminals T51 and T52. Thus, the terminals T51, T52, and T53 are gathered and, therefore, can be collectively coupled to a controller.

The controller, when the hemispherical touch area 15 is gripped and rotated with five fingers, generates a signal which causes, for example, page scroll operation etc., depending on a movement of a touch position along a periphery of the touch area 15 where the third electrodes 53 are provided. Also, the controller, when the user's finger is moved upward, downward, leftward, rightward etc. on the first to third electrodes 51, 52, and 53 in a diameter direction of the touch area 15 as viewed from above, detects a movement of a touch position to generate a signal which causes, for example, pointer move operation etc.

The controller also detects a touch position which is moved in a circular direction in the circular region of the set of the first electrodes 51 and the ring-shaped region of the set of the second electrodes 52 and the third electrodes 53, to generate a signal which causes, for example, pointer move operation etc.

A guide groove corresponding to the second or third electrodes may be optionally provided in order to guide rotation operation of the intermediate ring portion (second electrodes 52) or the perimeter ring portion (third electrodes 53). Alternatively, a ring-shaped rib (convex portion) may be provided between each ring portion and the first electrodes provided in the center portion. As a result, the operability of the touch panel device 10 can be improved.

Therefore, also in this embodiment, as in the fourth embodiment, the number of types of touch input operation can be increased, thereby significantly improving the convenience of the user, and reducing the load of calculation required for signal generation.

### Sixth Embodiment of the Invention

FIG. 7 shows a sixth embodiment of the present invention.

FIG. 7 is a perspective view schematically showing a configuration of a liquid crystal display device 1 according to the sixth embodiment.

While, in the first to fifth embodiments, the touch position detection electrodes 11 and 12 are formed along the surface of the convex substrate 13, in the sixth embodiment touch position detection electrodes 11 and 12 are formed along a surface of a concave substrate 13.

Also in this case, not only touch input can be performed on the curved touch panel device 10 with high operability, but also the number of types of touch input operation can be increased, whereby the convenience of the user can be significantly improved. In addition, a predetermined signal can be directly generated from a large number of types of touch input, resulting in a decrease in the load of calculation required for signal generation.

### Other Embodiments

Although, in the above embodiments, the example in which the display panel is the liquid crystal display panel 2 has been described, the present invention is not limited to this. For example, the present invention is similarly applicable to display devices including other display panels, such as organic EL display panels etc.

Although, in the above embodiments, the example in which the substrate 13 has a rotationally symmetric curved surface has been described, the present invention is not limited to this. The present invention is applicable to substrates having other general curved surfaces. For example, the substrate surface may be in the shape of an egg, a cocoon, etc.

### INDUSTRIAL APPLICABILITY

As described above, the present invention is useful for curved touch panel devices, method for manufacturing the same, and display devices.

### DESCRIPTION OF REFERENCE CHARACTERS

1 LIQUID CRYSTAL DISPLAY DEVICE
2 LIQUID CRYSTAL DISPLAY PANEL
10 TOUCH PANEL DEVICE
11 FIRST ELECTRODE (TOUCH POSITION DETECTION ELECTRODE)
12 SECOND ELECTRODE (TOUCH POSITION DETECTION ELECTRODE)
13 SUBSTRATE
15 TOUCH AREA
16 CENTER PORTION
17 TIP PORTION
40 CONTROLLER (DETECTION CIRCUIT)
41 CAPACITANCE DETECTION CIRCUIT (DETECTION CIRCUIT)
42 IMPEDANCE DETECTION CIRCUIT (DETECTION CIRCUIT)
51 FIRST ELECTRODE (TOUCH POSITION DETECTION ELECTRODE)
52 SECOND ELECTRODE (TOUCH POSITION DETECTION ELECTRODE)
53 THIRD ELECTRODE (TOUCH POSITION DETECTION ELECTRODE)

1. A touch panel device comprising:
a touch area configured to detect a position or positions of a touch or touches made by a touching object;
a plurality of touch position detection electrodes provided in the touch area; and
a detection circuit configured to detect the touch position or positions based on a capacitance or capacitances formed between the touch position detection electrodes and the touching object,
wherein
the plurality of touch position detection electrodes include a first electrode and second electrodes formed along a curved substrate surface,
the first electrode has a center portion provided at a center of the touch area, and a plurality of tip portions radially extending from the center portion to reach a periphery of the touch area, and
the second electrodes are located in a region including the periphery of the touch area, and one of the second electrodes is located between each adjacent pair of the tip portions.

2. The touch panel device of claim 1, wherein
the curved substrate surface is a non-developable surface.

3. The touch panel device of claim 1, wherein
the curved substrate surface has rotational symmetry.

4. The touch panel device of claim 3, wherein
the detection circuit is configured to detect whether or not the center portion of the first electrode is touched, and detect at least one of a distance and an azimuth of the touch position from a center of the rotational symmetry.

5. The touch panel device of claim 3, wherein
the detection circuit is configured to detect the touch position which is moved from the tip portion on one side through the center portion to the tip portion on the opposite side, and detect the touch position which is moved along the periphery of the touch area.

6. The touch panel device of claim 5, wherein
the first electrode is coupled to the detection circuit in the plurality of tip portions as viewed from above, and
the detection circuit is configured to, when the touch position is moved between tips of the first electrode along the plurality of tip portions and the center portion, detect vertical or horizontal scroll operation based on changes in capacitance values detected from the plurality of tip portions.

7. The touch panel device of claim 1, wherein
the second electrodes are formed in the shape of a wedge.

8. The touch panel device of claim 1, wherein
the detection circuit includes a capacitance detection circuit configured to detect the capacitances occurring in the first and second electrodes, or an impedance detection circuit configured to detect impedances occurring in the first and second electrodes.

9. The touch panel device of claim 8, wherein
the second electrodes are coupled, separately or in groups, to the capacitance detection circuit or the impedance detection circuit.

10. The touch panel device of claim 8, wherein
the tip portions of the first electrode are coupled to the capacitance detection circuit or the impedance detection circuit, and
the detection circuit is configured to compare signals from the tip portions detected by the capacitance detection circuit or the impedance detection circuit, to detect the touch position or positions in the center portion, or scroll operation in a direction along a perimeter of the touch area.

11. The touch panel device of claim 9, wherein
the detection circuit is configured to compare signals from the second electrodes detected by the capacitance detection circuit or the impedance detection circuit, to detect the touch position or positions in a perimeter portion of the touch area, or scroll operation in a direction along a perimeter of the touch area.

12. The touch panel device of claim 8, wherein
the detection circuit is configured to compare signals from the tip portions detected by the capacitance detection circuit or the impedance detection circuit with signals from the second electrodes detected by the capacitance detection circuit or the impedance detection circuit, to detect the touch position or positions in a radial direction from the center of the touch area, or scroll operation in a direction along a perimeter of the touch area.

13. A touch panel device comprising:
a touch area configured to detect a position or positions of a touch or touches made by a touching object;
a plurality of touch position detection electrodes provided in the touch area; and
a detection circuit configured to detect the touch position or positions based on a capacitance or capacitances formed between the touch position detection electrodes and the touching object,
wherein
the plurality of touch position detection electrodes include a plurality of first electrodes and a plurality of second electrodes formed along a curved substrate surface,
the plurality of first electrodes are provided at a center of the substrate surface, and the set of the plurality of first electrodes as a whole is formed in the shape of a circle,
the plurality of second electrodes are provided outside the first electrodes, and the set of the plurality of second electrodes as a whole is formed in the shape of a ring, and
the detection circuit is configured to detect at least one of a distance and an azimuth of the touch position from a center of the rotational symmetry, and the touch position which is moved on the first and second electrodes in a diameter direction of the touch area as viewed from above.

14. The touch panel device of claim 13, wherein
the curved substrate surface is a non-developable surface.

15. The touch panel device of claim 13, wherein
the curved substrate surface has rotational symmetry.

16. The touch panel device of claim 15, wherein
the plurality of touch position detection electrodes include a plurality of third electrodes provided outside the second electrodes, and the set of the plurality of third electrodes as a whole is formed in the shape of a ring, and
the detection circuit is configured to detect the touch position which is moved on the first, second, and third electrodes in the diameter direction of the touch area as viewed from above.

17. A display device comprising:
the touch panel device of claim 1; and
a display panel facing the touch panel device.

18. The display device of claim 17, wherein
the display panel is a liquid crystal display panel.

19. A method for manufacturing a touch panel device including a touch area configured to detect a position or positions of a touch or touches made by a touching object, a plurality of touch position detection electrodes provided in the touch area, and a detection circuit configured to detect the touch position or positions based on a capacitance or capacitances formed between the touch position detection electrodes and the touching object, the method comprising the steps of:
forming a substrate having a curved surface; and
forming a transparent conductive film having a predetermined shape along the curved surface of the substrate to form a first electrode and second electrodes, wherein
in the step of forming the first and second electrodes, the first electrode is formed to have a center portion provided at a center of the touch area, and a plurality of tip portions radially extending from the center portion to reach a periphery of the touch area, and the second electrodes are located in a region including the periphery of the touch area, and one of the second electrodes is located between each adjacent pair of the tip portions.
